(19) United States
(12) Patent Application Publication
(10) Pub. No.: US 2016/0018343 A1
(43) Pub. Date: Jan. 21, 2016

(54) SAMPLE HOLDER FOR THE EXAMINATION OF SMALL SAMPLES CONTAINED IN A SUSPENSION

(71) Applicants: Deutsches Elektronen-Synchrotron DESY, Hamburg (DE); Paul Scherrer Institut, Villigen PSI (CH)

(72) Inventors: Alke Meents, Hamburg (DE); Ismo Vartiainen, Turgi (CH); Christian David, Lauchringen (DE)

(21) Appl. No.: 14/754,741

(22) Filed: Jun. 30, 2015

(30) Foreign Application Priority Data
Jul. 2, 2014 (DE) 202014103041.7

(51) Int. Cl. G01N 23/20; H01J 37/16

(52) U.S. Cl. CPC G01N 23/20025; H01J 37/16

(57) ABSTRACT

A sample holder for the examination of small particles contained in a suspension using X-rays or electron beams is depicted and described, wherein the sample holder includes a single-crystal substrate extending in a plane, the dimensions of which in the plane are several times larger than the dimensions perpendicular to the plane, wherein the substrate includes a first and a second surface, which run parallel to the plane, and wherein the substrate includes through-holes, which extend perpendicular to the plane and which run from the first to the second surface.

### CROSS-REFERENCE TO RELATED APPLICATIONS

This application claims the benefit and priority of German Utility Model No. 20 2014 103 041.7, filed Jul. 2, 2014, the disclosure of which is incorporated herein by reference.

### FIELD

The present disclosure relates to a sample holder for the examination of small samples contained in a suspension.

### BACKGROUND

This section provides background information related to the present disclosure which is not necessarily prior art.

Scattering experiments, in particular those using X-ray radiation, offer excellent opportunities for the examination of the structure of crystalline samples, for example. Usually this involves placing the samples or particles whose structures are to be examined in an X-ray beam and detecting the scattered radiation. This then provides information about the structure. Such methods are well-known from the prior art, however, the development of free-electron lasers in recent times has propelled these methods forwards once more.

In this context the term particles shall, for the purposes of the present invention, be understood to mean, in particular, samples with dimensions within a range of a few micrometers. These could be, for example, microcrystals of macromolecules, other organic or inorganic solids, or biological samples such as cells.

When very small samples such as the above-mentioned particles are to be examined using X-ray radiation, the first problem encountered is that preferably the samples alone should be irradiated without simultaneous sample holder irradiation, so as to prevent radiation scattered by the sample holder from also being detected. For this reason it is known from the prior art to mount such small samples, with dimensions in a range of several tens of μm, by means of a microscopic loop (“loop mounting method”).

However, in many cases, in particular in the case of macromolecules, it is only possible to grow much smaller particles, measuring a few micrometers or even smaller. So that such small particles can nevertheless also be examined, several alternative approaches have already been developed. Thus in one approach, for example, a sample holder is dispensed with, and the particles are sprayed in the form of a suspension current consisting of a solution containing particles in the region of the X-ray beam, wherein the suspension current must, however, contain a high concentration of particles, and then only a small fraction of these particles are actually irradiated and contribute to the measurement result.

As another alternative, substrate screens (“micro-mesh”) are often used, which have a mesh size of approximately 10 to 100 μm. In electron beam diffraction the material used for this screen is usually copper. A suspension containing the particles to be examined is deposited onto this netting. In order to now remove the surplus solution, filter paper is used to draw it away. However, this still also carries away a large portion of the microcrystals.

Another alternative is a carrier substrate, which has depressions in which the particles should become trapped. But in this case too, on the one hand, particles do not settle into virtually all of the depressions, and on the other hand, with the removal of the surplus solution a portion of the particles is still carried away here, too.

Finally, it is known from U.S. 2013/0112610 A1 for the carrier substrate, which also includes continuous uniform pores, to be formed by a network of vertically arranged carbon nanotubes.

This may be expected to result in improvements in terms of the removal of surplus solvent and, associated therewith, a reduction of the carry off of macromolecules already located in the correct position. However, both the known substrate screens and the carrier substrate generate a significant scattering background because the incident radiation also strikes them. With carbon nanotubes there is the additional problem of low thermal conductivity, which means that the energy introduced through the irradiation may be only poorly dissipated.

Accordingly, there remains a need in the art for a sample holder for the examination of very small particles contained in a suspension using X-ray or electron beam radiation, which reduces the interference of the actual measuring signal caused by scattering of the incident radiation on the sample holder.

### SUMMARY

This section provides a general summary of the disclosure, and is not a comprehensive disclosure of its full scope or all of its features.

In one form, the present disclosure provides a sample holder which includes a single-crystal substrate extending in a plane, the dimensions of which in the plane are several times larger than the dimensions perpendicular thereto, with the substrate thus being designed as a flat disk-shaped structure, wherein the substrate includes a first and a second surface, which run parallel to the plane, and wherein the substrate includes through-holes which extend perpendicular to the plane and which run from the first to the second surface.

The sample holder may be constructed from single-crystal material, in which through-holes can be introduced, wherein the through-holes can have dimensions of less than 10 μm in the plane in which the substrate lies.

As a result, the usually solid particles are retained, in particular at the inlet area of the through-holes, directly adjacent to one of the surfaces, while the liquid portion of the suspension can drain away through the through-holes. This makes it possible to easily deposit solid particles, such as microcrystals or biological macromolecules for example, onto the sample holder.

Furthermore, the single-crystal material of the sample holder permits the X-ray radiation that strikes the sample holder and is not scattered on the particles to be diffracted in the Bragg reflection directions of the single-crystal substrate. When monochromatic X-ray radiation is used, the scattered radiation caused by the sample holder spreads along clearly defined directions, which is easy to take into account when analyzing the measuring signal. In particular, it is then possible to exclude the scattered radiation from the measurement result. This means that the sample holder of the present disclosure permits one to extract the relatively small scattering signal that is generated through scattering of the incident beams on the particles from the total scattered radiation signal.

Furthermore, the sample holder of the present disclosure allows the particles, such as microcrystals for example, which are initially in suspension in a solution, to be easily deposited onto the sample holder. To do so, the suspension containing the particles can be deposited onto one side of the substrate. Then the liquid portion of the suspension is sucked away from the opposite side via the through-holes, wherein the particles accumulate in the area of the inlets of the through-holes.

Finally, the use of a high purity single-crystal material, such as silicon, for the sample holder renders it very unlikely that there would be any interaction of the incident radiation with contamination, which would again cause interference of the measuring signal, for example through X-ray fluorescence.

With the sample holder of the present disclosure it is also possible to first produce therein the protein crystals to be examined in such a way that in the through-holes a so-called lipidic cubic phase, for example of monolein and water, is formed. This cubic phase forms a three-dimensional lattice, in which the proteins to be examined can crystallize, which proteins are for this purpose deposited inside a solution onto the sample holder and then in the cubic phase diffuse into the through-holes and are made to crystallize there.

The dimensions of the through-holes measured in the plane, which is defined by the substrate, can be in a range of less than 10 μm. In addition, the dimensions can be less than 4 μm, preferably less than 2 μm and particularly preferably less than 1 μm. Such dimensions allow the arrangement in a periodic structure of precisely those categories of particles such as microcrystals, e.g. of biological macromolecules, that are relevant for examinations using X-ray radiation.

Furthermore, the through-holes can have a triangular, rectangular, or square cross-section or can generally have different shapes and cross-sections.

In order to simplify scanning of a sample holder, it can be advantageous to arrange the through-holes in a right-angled grid pattern, wherein adjacent through-holes have a spacing of between 2 and 40 μm.

Furthermore, the sample holder can be designed such that the through-holes have a first and a second section along their direction of extension, wherein the dimensions of the through-holes parallel to the plane are larger in the first section than in the second section. This graduated design of the through-holes can permit the particles to accumulate reliably in the area of the stages, while the liquid portion of the suspension can drain away when it is deposited.

Finally, in instances where the sample holder of the present disclosure is formed of single-crystal silicon, the cost of the sample holder is reduced (because single-crystal silicon can be produced inexpensively) and heat generated during irradiation can be easily dissipated (because single-crystal silicon has high heat conductivity). This is the case even when the sample holder has a small thickness. In addition, single-crystal silicon is available with very good crystal quality, which means that the material contributes virtually exclusively to the Bragg scattering.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a top view of a sample holder constructed in accordance with the teachings of the present disclosure;

FIG. 2 is a top view of an enlarged portion of the sample holder of FIG. 1, illustrating an area having through-holes;

FIG. 3 is a view similar to that of FIG. 2 but depicting the area with differently configured through-holes;

FIG. 4 is a cross-sectional view of the area of the sample holder that is depicted in FIG. 2, the view illustrating the construction of the through-holes; and

FIGS. 5A through 5E are views illustrating a method for depositing particles contained in a suspension onto the sample holder of FIG. 1.

Corresponding reference numerals indicate corresponding parts throughout the several views of the drawings.

### DETAILED DESCRIPTION

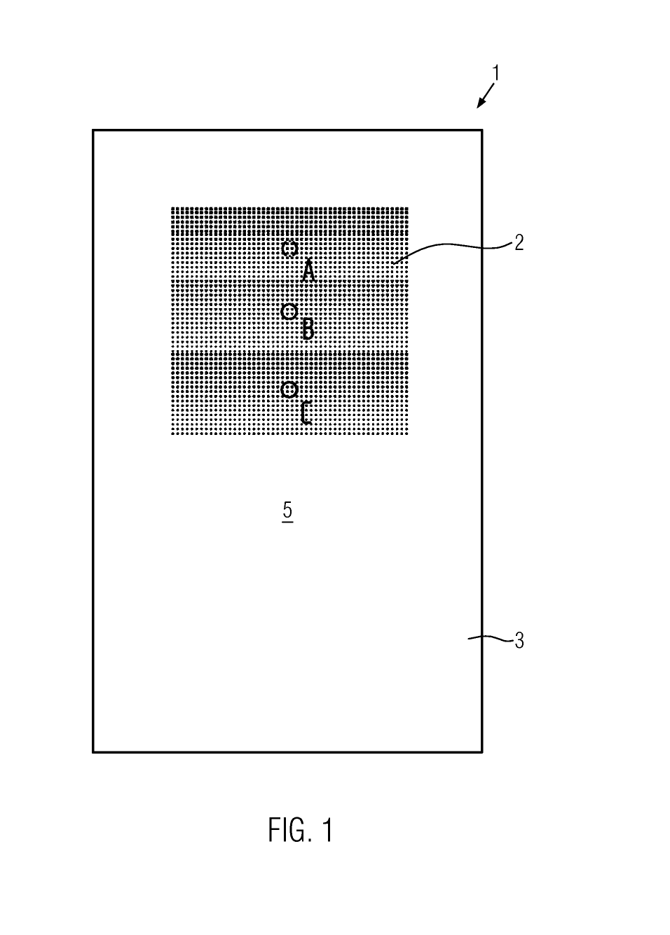

A first sample holder 1 constructed in accordance with the teachings of the present disclosure is shown in FIGS. 1, 2 and 4. The sample holder 1 can be formed from a substrate 3 made of single-crystal material, such as a single-crystal silicon. The thickness d of the single crystal (i.e., silicon single crystal in the example provided) can be between 3-30 μm. The entire substrate 3 can extend in a plane and can have dimensions of 2 mm by 4 mm in the plane in this case. These dimensions are significantly larger than the thickness d and therefore than the dimensions perpendicular to the plane.

The substrate 3 can include a first surface 5 and a second surface 7, which can run parallel to each other and extend along the plane in which the substrate 3 also extends. In one area 2 of the substrate 3, which in the exemplary embodiments described here has dimensions of 1.5 mm by 1.5 mm, a multitude of through-holes 9 can be provided. The through-holes 9 can be arranged in a desired pattern, such as a rectangular grid pattern, which extend from the first surface 5 to the second surface 7 through the substrate 3.

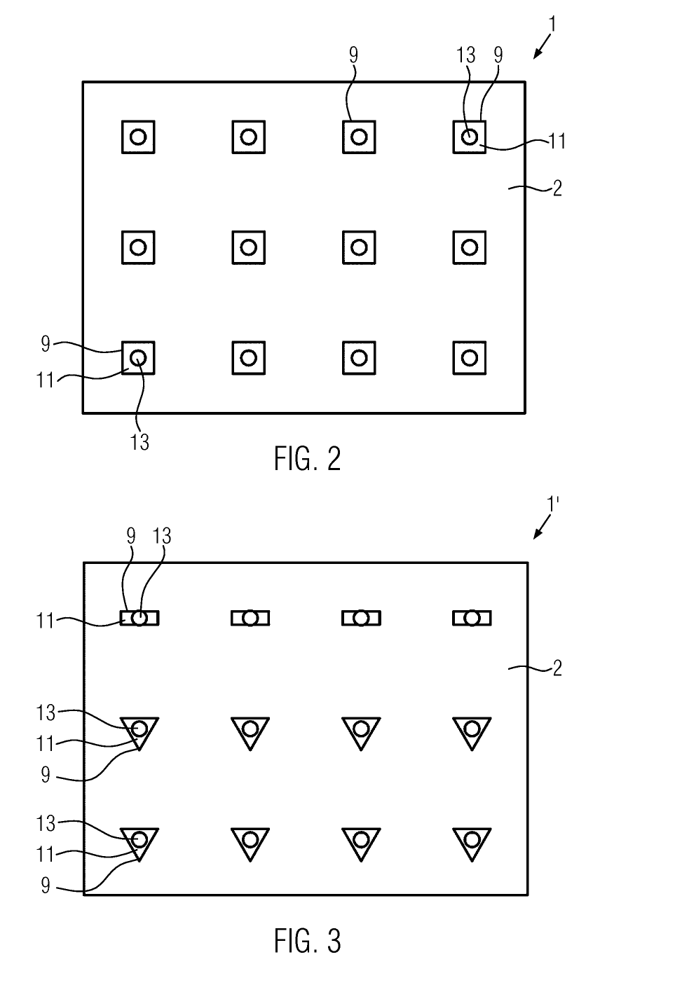

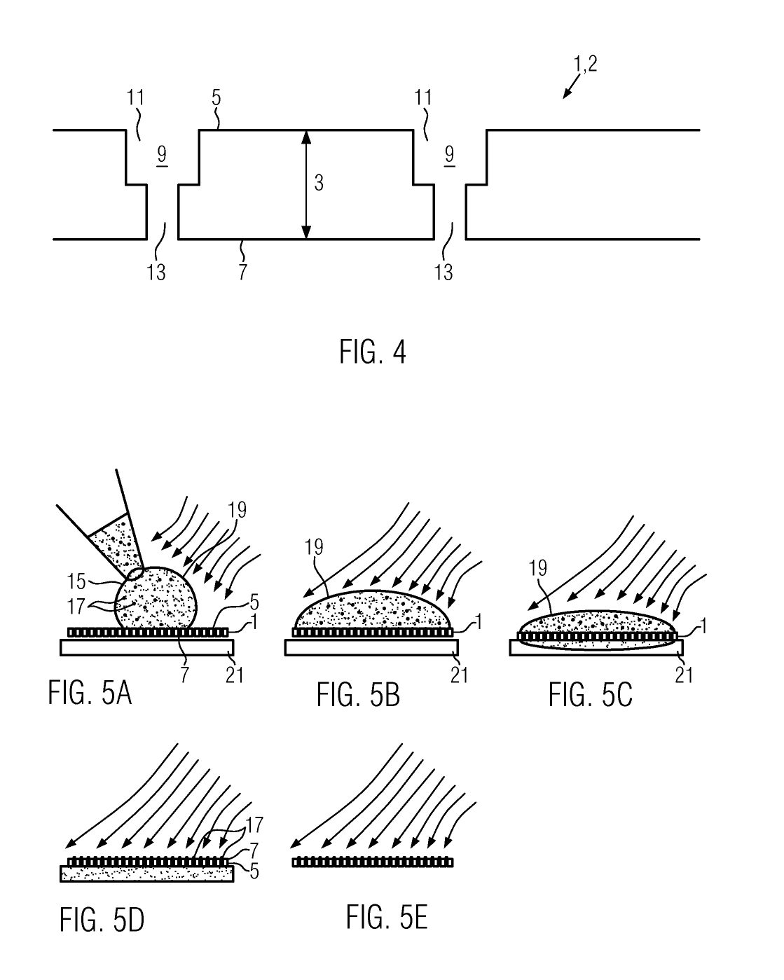

As can also be seen from FIG. 4, the through-holes 9 can be configured such that they have a first section 11 adjacent to the first surface 5 and a second section 13 adjacent to the second surface 7. The dimensions in the plane in the first section 11 are larger than in the second section 13. This means that the through-holes 9 are designed graduated, such that the particles, for example in the form of macromolecules, are preferably retained in the first section 11, when a suspension containing them flows from the first surface 5 to the second surface 7, through the through-holes 9. As can also be seen in FIG. 2, the first section 11 of the through-holes 9 in the sample holder 1 of the present disclosure can have a rectangular cross-section, while the second section 13 can have a circular cross-section.

In contrast to the sample holder of FIGS. 1, 2 and 4, a second sample holder 1′ constructed in accordance with the teachings of the present disclosure is shown in FIG. 3. The sample holder 1′ can be configured such that in the area 2, the first sections 11 of the through-holes 9 can have a rectangular or triangular cross-section, while the second sections 13 can have a circular cross-section. However, it is, in principle, also conceivable for the cross-sections of all of the through-holes 9, or at least of a section of them, to be generally polygonal.

The steps of a method are depicted in FIGS. 5A through 5E, by means of which particles 17 contained in a suspension 15 may be deposited for an examination, for example using X-ray radiation, onto the previously described exemplary embodiments of sample holders 1, 1′ according to the teachings of the present disclosure.

In one form, the method can include depositing the suspension 15 containing the particles 17 in the area 2 on the first surface 5 of the sample holder 1 as shown in FIG. 5A. The liquid portion 19 of the suspension 15 can be drawn away from the second surface 7 via the through-holes 9, for example with the help of absorbent paper as shown in FIGS. 5B and 5C. When the liquid has been completely removed as shown in FIG. 5D and 5E, only the particles 17 remain on the first surface 5 in the area of the first sections 11 of the through-holes 9.

It is also possible to produce the protein crystals that are to be examined in the sample holder 1 of the present disclosure. A so-called lipidic cubic phase of monolein and water, for example, can be formed in the through-holes 9. This cubic phase forms a three-dimensional lattice, in which the proteins to be examined can crystallize, which for this purpose are also introduced into the through-holes 9. Both can be drawn into the through-holes 9 as described.

When performing the method depicted in FIG. 5, the sample holder 1 can be subjected to an air current having a defined humidity, or an inert gas such as nitrogen or argon, for example, in order to prevent drying out or reaction of the particles with the ambient air.

The sample holder 1 can be arranged in a measuring arrangement in such a way that the first surface 5 faces an X-ray radiation source, so that the sample holder 1 can be scanned with the X-ray radiation, wherein only the areas in which through-holes 9 are provided are irradiated with X-ray radiation. This procedure can be simplified in situations where the through-holes 9 are arranged in a rectangular grid pattern. During the scanning procedure a rotation of the sample holder 1 is also possible.

During the irradiation the scattered radiation is detected, wherein, however, due to the single-crystal structure of the sample holder 1, radiation scattered thereon is scattered in the Bragg reflection directions of the sample holder 1. The radiation scattered by the sample holder 1 can be easily simulated and excluded from the overall scattered radiation image. Furthermore, through a targeted selection for the orientation of the substrate, it is possible that in a scattering experiment the Bragg reflections are not in a diffraction position and thus no Bragg reflections of the substrate occur. This permits determination of only the radiation which is scattered through scattering on the particles 17. Thus the interference in the measurement results caused by the sample holder 1 can be easily taken into account in the analysis. Furthermore, the relatively high thermal conductivity of single-crystal silicon allows the heat generated when the X-ray radiation strikes the sample holder 1 to be rapidly dissipated.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A sample holder for the examination of small particles contained in a suspension using X-rays or electron beams, the sample holder comprising a single-crystal substrate (3) that extends in a plane, the sample holder having length and width dimensions in the plane in the plane are several times larger than the a dimension (d) of the sample holder taken in a direction that is perpendicular to the plane, wherein the substrate (3) includes a first and a second surface (5, 7), which run parallel to the plane, and wherein the substrate (3) includes through-holes (9) which extend perpendicular to the plane and which run from the first to the second surface (5, 7).

2. The sample holder of claim 1, wherein the through-holes (9) have dimensions in the plane of less than or equal to 10 μm.

3. The sample holder of claim 2, wherein each of the through-holes (9) has a round, triangular, rectangular, or square cross-sectional shape.

4. The sample holder of claim 2, wherein the in-plane dimensions of the through-holes are less than or equal to 4 μm.

5. The sample holder of claim 4, wherein each of the through-holes (9) has a round, triangular, rectangular, or square cross-sectional shape.

6. The sample holder of claim 4, wherein the in-plane dimensions of the through-holes are less than or equal to 2 μm.

7. The sample holder of claim 6, wherein each of the through-holes (9) has a round, triangular, rectangular, or square cross-sectional shape.

8. The sample holder of claim 6, wherein the in-plane dimensions of the through-holes are less than or equal to 1 μm.

9. The sample holder of claim 8, wherein each of the through-holes (9) has a round, triangular, rectangular, or square cross-sectional shape.

10. The sample holder of claim 2, wherein each of the through-holes (9) has a round, triangular, rectangular, or square cross-sectional shape.

11. The sample holder of claim 10, wherein each of the through-holes (9) has a first and a second section (11, 13) and wherein the dimensions of the through-holes (9) parallel to the plane in the first section (11) are larger than in the second section (13).

12. The sample holder of claim 11, wherein the through-holes (9) are arranged in a right-angled grid pattern.

13. The sample holder of claim 12, wherein each adjacent pair of the through-holes (9) has a spacing of between 2 and 40 μm.

14. The sample holder of claim 1, wherein each of the through-holes (9) has a first and a second section (11, 13) and wherein the dimensions of the through-holes (9) parallel to the plane in the first section (11) are larger than in the second section (13).

15. The sample holder of claim 9, wherein the single-crystal substrate (3) is formed of silicon.

16. The sample holder of claim 1, wherein each of the through-holes (9) has a first and a second section (11, 13) and wherein the dimensions of the through-holes (9) parallel to the plane in the first section (11) are larger than in the second section (13).

17. The sample holder of claim 1, wherein the through-holes (9) are arranged in a right-angled grid pattern.

18. The sample holder of claim 1, wherein each of the through-holes (9) has a round, triangular, rectangular, or square cross-sectional shape.

19. The sample holder of claim 1, wherein the single-crystal substrate (3) is formed of silicon.
